(19) United States
(12) Patent Application Publication
(10) Pub. No.: US 2001/0003014 A1
(43) Pub. Date: Jun. 7, 2001

(54) Plasma CVD apparatus and plasma CVD method

(75) Inventor: Katsuhisa Yuda, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/729,193

(22) Filed: Dec. 5, 2000

(30) Foreign Application Priority Data
Dec. 7, 1999 (JP) 348157/1999

(51) Int. Cl. B05D 3/14; C23C 16/509

(52) U.S. Cl. 427/562; 118/723 E

(57) ABSTRACT

A remote plasma CVD apparatus is disclosed, in which oxygen gas 18 is supplied to a high frequency wave applying electrode 1 to cause reaction of oxygen radicals and oxygen molecules 21 with monisilane gas 19, which is introduced into part of a substrate processing zone R outside oxygen plasma 22. The apparatus comprises a plasma confining electrode 20, which has jetting holes for supplying monosilane gas 19 to the substrate processing zone R. The electrode 20 is spaced apart from a substrate 3 (i.e., deposition substrate) by a distance no longer than about 1,500 λ_{g} of the mean free path in the substrate processing zone R at the time of film formation. The member 20 has a hollow structure, and accommodates dispersing plates (i.e., a first and a second dispersing plate) for uniformalizing monosilane gas (i.e., neurtral gas) in it. Thus both of suppression of excessive progress of gas phase chemical reaction and homogeneous film formation in a remote plasma CVD apparatus for forming film by gas phase chemical reaction are realized.

### BACKGROUND OF THE INVENTION

This application claims benefit of Japanese Patent Application No. 11-348157 filed on Dec. 7, 1999, the contents of which are incorporated by the reference.

The present invention relates to plasma CVD (chemical vapor deposition) apparatus and plasma CVD method using the same and, more particularly, to a remote plasma CVD apparatus which separates a plasma forming zone and a substrate processing zone and also to a method of forming a large area, homogeneous and dense film by remote plasma CVD.

Among various types of plasma CVD apparatus for forming a film on a substrate while suppressing plasma damage are a remote plasma CVD apparatus, which separates a plasma forming zone and a substrate processing zone R. The CVD film formation using this remote plasma CVD apparatus implements a very important technique as thin film forming process for manufacturing high reliability devices and high performance devices.

As for remote plasma CVD apparatus, which can be used for a large area substrate processing, such as a switching transistor forming process and a drive circuit transistor forming process for a large area flat panel display, or as a process of processing a large diameter silicon wafer, a parallel plate remote plasma CVD apparatus is disclosed in, for instance, Japanese Laid-Open Patent No. 5-21393.

FIG. 7 shows a parallel plate plasma CVD apparatus in this prior art remote plasma CVD apparatus. As shown, the apparatus comprises a plasma confining electrode 8, which is obtained by using a mesh plate having a plurality of holes and disposed between a high frequency wave applying electrode 1 and a back electrode 2, on which a substrate is set.

In this parallel plate remote plasma CVD apparatus, plasma 6 is confined between the high frequency wave applying electrode 1 and the plasma confining electrode 8.

Such gas as neutral radicals 4 is supplied from large area homogenous plasma confined between the two parallel plates, i.e., high frequency wave applying electrode 1 and plasma confining electrode 8, to a substrate processing zone R. The apparatus thus features that a large area uniform distribution of neutral radicals 4 for the like supplied to the substrate processing zone R is obtained within the top surface of substrate 3, so that a thin film forming process can be carried out uniformly over the substrate 3, which may have a large area as well.

In this prior art apparatus, the plasma confining electrode 8, i.e., mesh plate, has radical passing holes 5 for passing radicals 4 therethrough and also neutral gas jetting holes 9, which are formed near the holes 5 and serve to jet out neutral gas 10 from them. A large area uniform film depositing process is thus possible as process of forming a film on the substrate 3 even in the case of utilizing gas phase reaction between the radicals 4 and the neutral gas 10.

When carrying out film formation (i.e., film forming process) involving gas phase chemical reaction in the substrate processing zone R in the parallel plate remote plasma CVD apparatus as shown in FIG. 7, first gas plasma (i.e., plasma 6) which contributes to the reaction is formed, and radicals (i.e., radicals 4) of excited first gas and non-excited first gas are supplied from the plasma through the radical passing holes 5 in the plasma confining electrode 8 to the substrate processing zone R for reaction second gas supplied from the neutral gas jetting holes 9 to form a film formation precursor, which is necessary for the film formation.

As an example, when carrying out silicon oxide film formation by reaction between monosilane (SiH₄) and oxygen (O₂) , oxygen is supplied as first gas, and monosilane as second gas.

The plasma confining electrode 8 has large numbers of radical passing holes 5 and neutral gas jetting holes 9. Thus, if the second gas (i.e., neutral gas 10) is supplied uniformly from the large number of neutral gas jetting holes 9, gas phase reaction can be brought about uniformly over the top surface of substrate 3 in the substrate processing zone R, and a homogeneous film can be formed on the substrate surface.

Owing to the above features, the parallel plate remote plasma CVD apparatus is considered to be promising as method of forming silicon oxide (SiO₂) film and silicon nitride Si₃N₄ or SiₓN_{y} layers as gate insulating film of thin film transistor on large area glass substrate, method of forming amorphous silicon film as active layer or gate electrode of thin film transistor on the large area glass substrate, method of forming silicon oxide film or silicon nitride film as inter-layer insulating film of transistor element on the large area glass substrate, and so forth.

The plasma confining electrode 8 in the above prior art apparatus (disclosed in Japanese Patent Laid-Open No. 5-21393), has a hollow structure having the neutral gas jetting holes 9, which are, as described before, formed near the radial passing holes 5 for surface uniform supply of neutral gas 10.

In the plasma confining electrode 8 having the hollow structure, as shown in a side and a top view of the electrode 8 in FIGS. 8 and 9, the radical passing holes 5 and the neutral gas jetting holes 9 are formed independently (or separately) of one another. Thus, radicals 4 and neutral gas 10 are not mixed and reacted with one another in the space in hollow electrode 8.

As shown in FIG. 9 or 10, in the prior art apparatus neutral gas 10 is supplied to the hollow plasma gas confining electrode 8 from the outside of the evacuated chamber. Specifically, neutral gas 10 is supplied to the space in the electrode 8 from a neutral gas supply duct line, which is provided on an end surface of the electrode 8.

In the gas supply method in this prior art case, the pressure in the space in the plasma confining electrode 8 is substantially the same as the film formation pressure in the substrate processing zone R, i.e., several ten to several hundred Torr.

Therefore, as schematically shown in FIG. 11, neutral gas 10 is mostly jetted out from neutral gas jetting holes 9 in the neighborhood of the connection juncture between neutral gas supply duct line 12 and the plasma confining electrode 9, and are jetted out at lower rates from jetting holes 9 remoter from the duct line 12. This is a drawback in that it is difficult to jet out neutral gas 10 uniformly over the surface of the substrate 3.

In this circumstance of difficulty of uniformly jetting out neutral gas 10 over the substrate surface is difficult, it is conceivable to increase the distance D of the plasma confining electrode 8 for jetting out neutral gas 10 therefrom from the substrate 3 in order to form a homogeneous film within the substrate surface.

In the case when gas phase chemical reaction is brought about between the second gas (i.e., neutral gas 10), which is supplied non-uniformly over the substrate surface in the substrate processing zone, with the first gas, reaction product (i.e., film formation precursor that is generated as a result of gas phase chemical reaction is distributed non-uniformly over the substrate surface in the neighborhood of the second gas supply port.

With the increased distance D as noted above, however, sufficient time is provided for the second gas and the reaction product to be dispersed in directions parallel to the surface of the substrate 3 until reaching of the substrate 3. Thus, uniform distribution is obtainable within the surface of the substrate 3 at the time of reaching the substrate 3.

In this film forming method, it is possible to obtain the more uniform distribution the greater the distance D between the plasma confining electrode 3 and the substrate 3 with respect to the width W of the CVD chamber.

As an example, when carrying out film formation on a glass substrate of 500 mm×600 mm, the width W of the CVD chamber is about 800 mm, and in this case sufficient uniformalizing effect is obtainable with the same length, (i.e., about 100 mm) between the plasma confining electrode and the substrate.

In the film formation by the gas phase chemical reaction, however, if the distance D between the plasma confining electrode 8 with the neutral gas jetting holes 9 for jetting neutral gas 10 therefrom and the deposition base substrate (i.e., substrate 3) is increased, the gas phase reaction between the first gas containing neutral gas radicals and the second gas proceeds excessively to result in process of growth of particles (i.e., film formation precursor) in the gas phase in the substrate processing zone R and consequent deposition of the grown particles on the substrate surface, thus resulting in the generation of a coarse film.

As an example, in the formation of a silicon oxide film by gas phase chemical reaction of monosilane and oxygen, SiOₓ particles (i.e., film formation precursor) are grown in the gas phase in the substrate processing zone R.

Such coarse film as formed in the above way is high in defect density, high in leak current and low in dielectric strength and, therefore, can not be used as thin film transistor gate insulating film and the like.

### SUMMARY OF THE INVENTION

The present invention was made in view of the above background, and it seeks to provide a remote plasma CVD apparatus and a remote plasma CVD method capable of providing film formation precursor, which permits dense and surface uniform film deposition on deposition base substrate without particle growth due to excessive gas phase chemical reaction in the film formation in a remote plasma CVD method based on the gas phase chemical reaction.

According to an aspect of the present invention, there is provided a plasma CVD apparatus comprising a substrate processing zone with a deposition substrate disposed therein, a plasma generating zone for generating plasma of first gas, and a plasma confining electrode for separating the substrate processing zone and the plasma generating zone and confining the first gas and having holes for passing first gas containing neutral radicals from the first gas plasma, wherein: the plasma confining electrode has a hollow structure, accommodates gas dispersing plates for uniformalizing second gas in the plasma confining electrode, and has holes for introducing the second gas into the substrate processing zone to form a desired film on the deposition substrate by gas phase chemical reaction of the first gas containing neutral radicals and the second gas with each other; and the vertical distance between the plasma confining electrode and the deposition substrate is no longer than 1,500 times the mean free path λ_{g} blend gas of neutral radicals and the second gas in the substrate processing zone at the time of film formation.

A plurality of parallel dispersing panels are disposed as the afore-said dispersing plates in the plasma confining electrode.

According to another aspect of the present invention, there is provided a plasma CVD film forming method comprising: a first step of forming plasma of first gas in a plasma generating zone; a second step of confining the plasma in the plasma generating zone with a plasma confining electrode member; a third step, in which the plasma confining electrode member passes through holes formed therein neutral radicals from the plasma to a substrate processing zone; a fourth step, in which the plasma confining electrode member supplies uniformalized second gas, with dispersing plates disposed in the member for uniformalizing the second gas, to the substrate processing zone with a deposition substrate disposed therein; and a fifth step of forming a desired film on the deposition substrate by gas phase chemical reaction of the first gas containing neutral radicals and the second gas;wherein: the vertical distance between the plasma confining electrode member and the deposition substrate is no longer than about 1,500 times the mean free path λ_{g} in the substrate processing zone at the time of film generation.

According to other aspect of the present invention, there is provided a plasma CVD apparatus comprising a substrate processing zone with a deposition substrate disposed therein, a plasma generating zone for generating plasma of first gas, and a plasma confining electrode for separating the substrate processing zone and the plasma generating zone and confining the first gas and having holes for passing first gas containing neutral radicals from the first gas plasma, wherein: the plasma CVD apparatus further comprises a gas introducing member disposed between the plasma confining electrode member and the deposition substrate and having a plurality of holes, through which second gas is introduced into the substrate processing zone to form a desired film on the deposition substrate by gas phase chemical reaction between the first gas containing neutral radicals and the second gas; and the gas introducing member has a hollow structure, accommodates dispersing plates for uniformalizing the second gas in it and is vertically spaced apart by a distance no longer than about 1,500 times the mean free path λ_{g} in the substrate processing zone.

A plurality of parallel dispersing plates are disposed as the afore-said dispersing planes in the gas introducing member.

According to still other aspect of the present invention, there is provided a plasma CVD film forming method comprising: a first step of forming plasma of first gas in a plasma generating zone; a second step of confining the plasma in the plasma generating zone with a plasma confining electrode member; a third step, in which the plasma confining electrode member supplies first gas containing neutral radicals through its holes from the plasma to a space between the plasma confining electrode member and a gas introducing member; a fourth step, in which the gas introducing member passes first gas containing neutral radicals through its holes to the substrate processing zone with a deposition substrate disposed therein; a fifth step, in which the gas introducing member supplies uniformalized second gas to the substrate processing zone with dispersing plates disposed in it for uniformalizing the second gas; and a sixth step of forming a desired film on the deposition substrate by gas phase chemical reaction between the first gas containing neutral radicals and the second gas wherein: the gas introducing member is spaced apart from the deposition substrate by a vertical distance no longer than about 1,500 times the mean free path λ_{g} in the substrate processing zone.

Other objects and features will be clarified from the following description with reference to attached drawings.

### BRIEF DESCRIPTION OF THE DRAWINGS

FIG. 1 is a schematic side view showing a parallel plate remote plasma CVD apparatus as a first embodiment of the present invention;

FIG. 2 is a schematic sectional view showing a plasma confining electrode accommodating dispersing plates in the first embodiment of the present invention;

FIGS. 3A and 3B are schematic plan views showing an upper and a lower plate of the plasma confining electrode accommodating dispersing plates in the first embodiment of the present invention;

FIGS. 4A and 4B are schematic plan views showing the dispersing plates in the first embodiment of the present invention;

FIG. 5 is a view showing leak current characteristics of deposited silicon oxide films;

FIG. 6 is a schematic side view showing a parallel plate remote plasma CVD apparatus as a second embodiment of the present invention;

FIG. 7 is a schematic side view showing a prior art parallel plate remote plasma CVD apparatus;

FIG. 8 is a schematic sectional view showing a plasma confining electrode having a hollow structure in the prior art apparatus;

FIG. 9 is a schematic plan view showing the plasma confining electrode having the hollow structure in the prior art;

FIG. 10 is a schematic side view showing the prior art parallel plate remote plasma CVD apparatus for describing a method of supplying neutral gas to the hollow plasma confining electrode from the outside of vacuum chamber; and

FIG. 11 is a schematic sectional view illustrating the manner of gas jetting from the hollow plasma confining electrode in the prior art apparatus.

### PREFERRED EMBODIMENTS OF THE INVENTION

Preferred embodiments of the present invention will now be described with reference to the drawings.

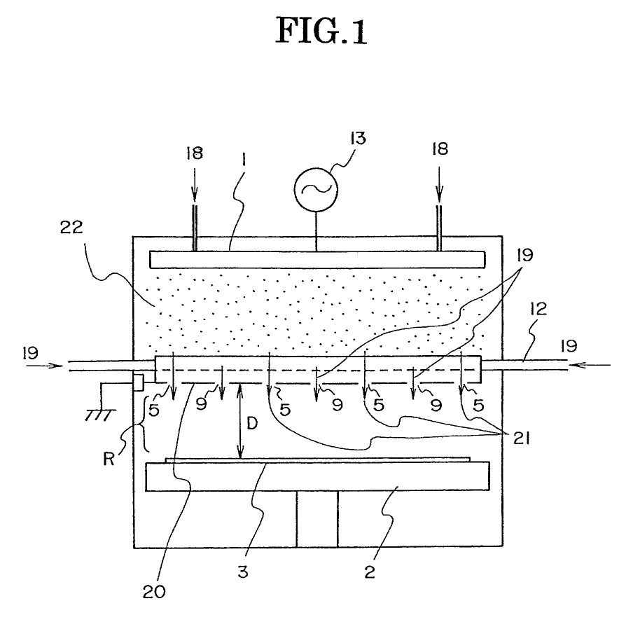

FIG. 1 is a schematic schematic sectional view showing the construction of an embodiment of remote plasma CVD (chemical vapor deposition) apparatus according to the present invention. An embodiment of the present invention will now be described in detail. The embodiment of the present invention will now be described in connection with silicon oxide film formation in an oxygen/silane parallel plate remote plasma CVD apparatus as an example with reference to the Figure. Elements like those in the prior art example are designated by like reference numerals, and are not described.

As basically shown in FIG. 1, the parallel plate flat remote plasma CVD apparatus comprises a vacuum chamber capable of being evacuated, a high frequency power supply 13, a high frequency wave applying electrode 1, a back electrode 2 supporting a substrate 3, a plasma confining electrode 20, which has radial passing holes for passing gas containing neutral radicals therethrough and is electrically grounded, and a neutral gas supply duct line 12 for supplying neutral gas (for instance monosilane 19) into the plasma confining electrode 20 from an end thereof.

The plasma confining electrode 20 accommodates dispersing members having radical passing holes and neutral gas jetting holes.

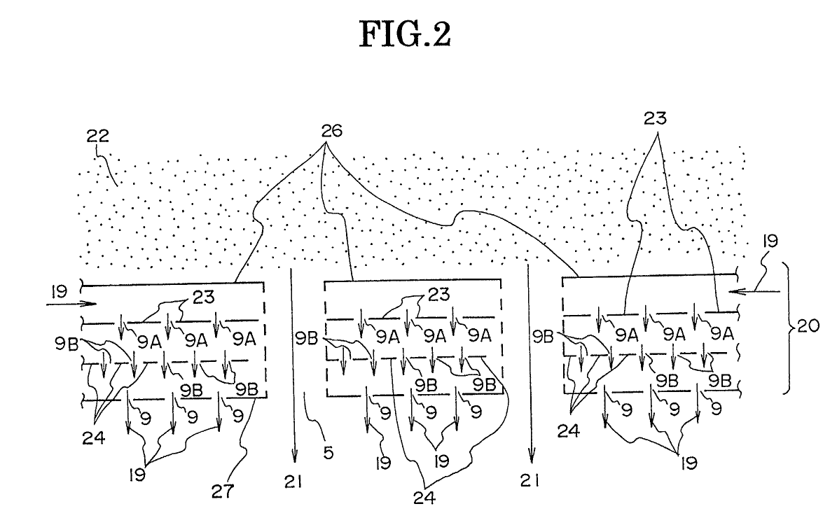

FIG. 2 is a schematic sectional view having the plasma confining electrode 20 having the dispersing plates. In the Figure, a plurality of dispersing plates, i.e., a first and a second dispersing plate 23 and 24 in this embodiment, for uniformly dispersing monosilane gas (i.e., neutral gas) 19, are provided (i.e., disposed) in the apace defined between an upper and a lower plate 26 and 27 in the plasma confining electrode 20.

In FIG. 2, monosilane gas 19 is supplied to the space between the upper plasma confining electrode plate 26 and the first gas dispersing plate 23, then uniformalized through holes 9A in the first dispersing plate 3 and then through holes 9B in the second gas dispersing plate 24, and then jetted through neutral gas jetting holes 9 in the plasma confining electrode lower plate 27 in a plane uniform fashion toward the base 3.

The holes 9A, 9B and neutral gas jetting holes 9 are provided separately (i.e., independently) of the radical passing holes 5 in the plasma confining electrode 20 such that oxygen radicals and oxygen molecules 21 are not mixed with monosilane gas 19. To this end, the radical passing holes 5 are formed as continuous holes 5 by walls isolating them from the zone, in which monosilane gas is present.

While in the case of FIG. 2 two dispersing panels, i.e., the first and second dispersing plates 23 and 24, are shown, it is also possible to use only a single dispersing plate or two or more dispersing plates.

The diameter of the opening of the radical passing holes 5, which are continuous between the upper and lower plasma containing electrode plates 26 and 27 set to the length roughly less than double the plasma device length of generated oxygen plasma 22.

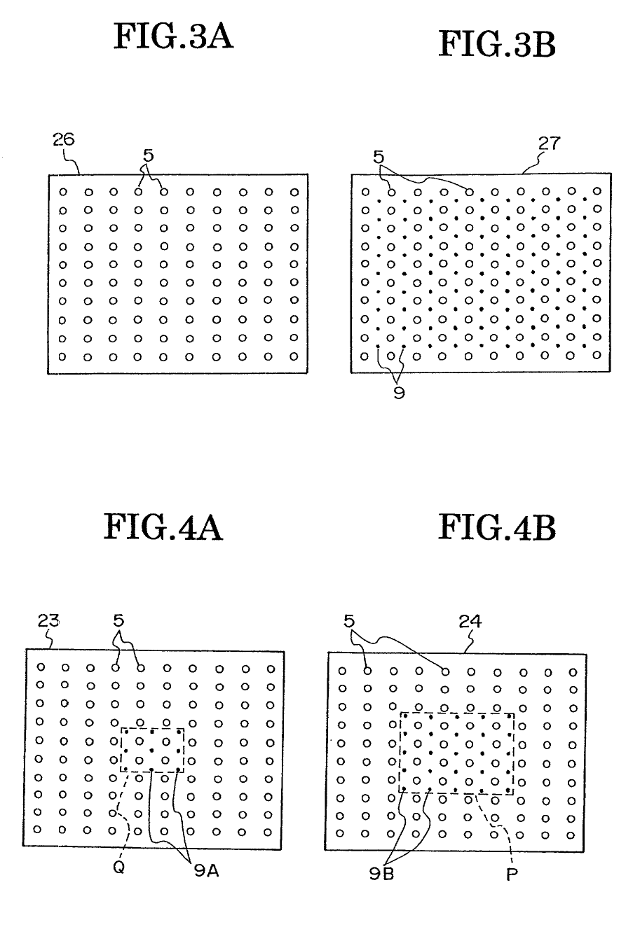

FIGS. 3A and 3B are plan views showing the upper and lower plasma containing electrode plates 26 and 27.

Referring to FIG. 3A, the upper plasma confining electrode plate 26 has radical passing holes 5, which are provided at uniform intervals and serve to pass gas containing neutral radicals through them.

Referring to FIG. 3B, in the lower plasma confining electrode plate 27 the radical passing holes 5 are open at predetermined intervals for passing the gas containing neutral radicals. The plate 27 also has neutral gas jetting holes 9 formed at uniform intervals and at positions not coincident with the radical passing holes 5.

FIGS. 4A and 4B are plan views showing dispersing plates, i.e., first and second dispersing plates 23 and 24. The two dispersing plates, i.e., the first and second dispersing plates 23 and 24, correspond to corresponding first and second dispersing plates 23 and 24.

Referring to FIG. 4A, the first dispersing plate 23 is penetrated by the radical passing holes 5 spaced apart at uniform intervals for passing gas including neutral radicals, and it also has neutral gas passing holes 9, which are formed at uniform intervals in its predetermined area Q near the center at positions non-coincident with the radical passing holes 5.

Referring to FIG. 4B, the second dispersing plate 24 has the radical passing holes 5 spaced apart at uniform intervals for passing neutral radicals, and it also has neutral gas passing holes 9, which are formed at uniform intervals in its predetermined area P near the center at positions non-coincident with the radical passing holes 5.

In the case when the two dispersing plates, i.e., the first and second dispersing plates 23 and 24, are aligned to each other in their installation in the plasma confining electrode 20, the area P covers and broader than the area Q.

In other words, the second dispersing plate 24 has the neutral gas passing holes 9, which are provided not only at the positions corresponding to those in the first dispersing plate 23 but also in an outside area.

Although it is possible to provide neutral gas passing holes at uniform intervals over the entire dispersing plate area, by contriving the disposition of holes of a plurality of dispersing plates in FIGS. 4A and 4B as described before, it is possible to prevent jetting-out of gas at high rates into the substrate processing zone R near the neutral gas supply duct line 12 and thus obtain more plane uniform supply of neutral gas (for instance, monosilane gas 19) over the surface of the substrate 3.

Furthermore, it is possible to dispose the two dispersing plates, i.e., the first and second dispersing plates 23 and 24, in the plasma confining electrode 20 such that their like holes, i.e., the holes 9A and 9B, through which monosilane (i.e., neutral gas) 19 flows, are deviated from one another in plan view (i.e., not in vertical lines).

Now, a method of forming a silicon oxide film on the surface of the substrate 3 with one embodiment of the remote plasma CVD apparatus will now be described with reference to FIGS. 1 to 4A and 4B.

Oxygen gas 18 is introduced into the high frequency wave applying electrode 1 in the CVD chamber in an evacuated state (under a predetermined pressure), and is then supplied uniformly from the bottom of the electrode 1 toward the plasma confining electrode 20. Thus, glow discharge of the oxygen gas is brought about in the space between the electrode 1 and the plasma confining electrode 20 (accommodating the first and second dispersing plates 23 and 24 shown in FIG. 4).

As a result of the glow discharge, oxygen plasma 22 is generated, which is efficiently confined between the high frequency wave applying electrode 1 and the plasma confining electrode 20.

As a result, a situation is set up that the plasma density of the oxygen plasma 22 is about 10¹⁰ cm⁻³ while that in the space between the high frequency wave applying electrode 20 and the back electrode 2 (or substrate 3) is about 10⁵ to 10⁶ cm⁻³.

This situation indicates that although electrons, oxygen atom ions, oxygen molecule ions, oxygen atom radicals, oxygen molecule radicals and oxygen molecules are present in the oxygen plasma 22, electrons and ions introduced in the zone outside the plasma are substantially negligible.

Thus, in the space 22 outside the plasma 22, oxygen atom radicals, oxygen molecule radicals and non-excited oxygen molecules undergo reaction with the monosilane gas 19 jetted out into the substrate proceding zone R and thus contribute to the silicon oxide film formation.

Oxygen radicals and oxygen molecules 21 are dispersed through the radical passing holes 5 into the substrate processing zone R for gas phase chemical reaction with the monosilane gas 19 jetted out from the neutral gas jetting holes 9.

As a result of the gas phase chemical reaction, silicon oxide precursor (i.e., film formation precursor), such as SiOₓ, SiOₓH_{y} and SiH_{y} is formed and deposited on the surface of the substrate 3, thus forming a silicon oxide film on the substrate 3.

The plasma confining electrode 20 is spaced apart from the substrate 3 by a distance D (i.e., vertical distance), which is set to be shorter than about 1,500 (excluding 0) times the mean free path λ_{g} of the blend gas of oxygen (i.e., oxygen radicals and oxygen molecules 21) and monosilane in the substrate processing zone R. This distance D has an effect of preventing excessive progress of the gas phase chemical reaction. It is thus impossible that the silicon oxide precursor, such as SiOₓ, SiOₓH_{y} and SiH_{y}, undergoes particle growth to a particle size in the gas phase in the substrate processing zone R.

For example, under conditions with the gas temperature of 300° C. and the chamber pressure of 250 mTorr, the mean free path λ_{g} of the oxygen/monosilane blend gas is about 60 μm, and in this case the distance D between the plasma confining electrode and the substrate may be set to 90 mm or below.

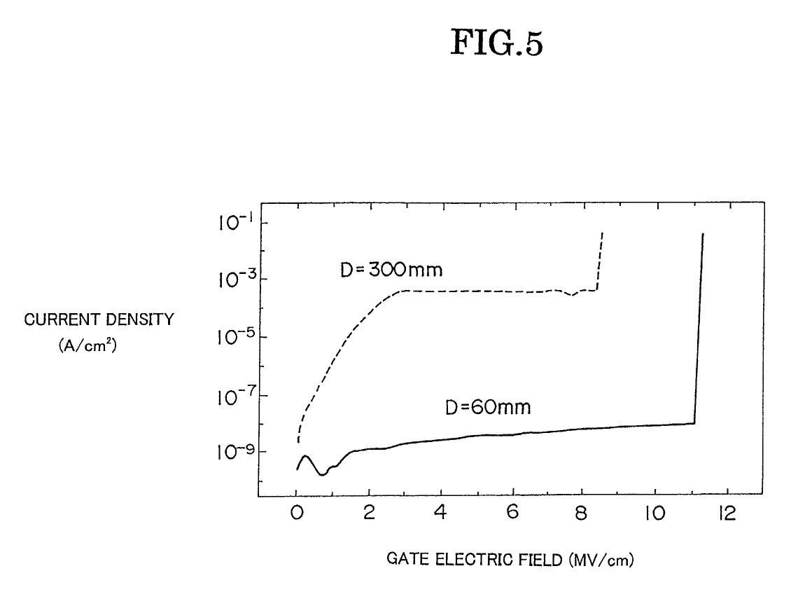

FIG. 5 shows leak current characteristics obtained in an experimental example of silicon oxide film formation. In this example, silicon oxide films were formed by setting, as experiment conditions, the substrate temperature to 300° C., the pressure in the substrate processing zone R to 250 mTorr, the flow rate of oxygen supplied through the high frequency wave applying electrode 1 to the plasma zone to 800 sccm, and the flow rate of monosilane gas supplied to the neutral gas supply duct line 12 to 5 sccm, and used as gate insulating film of MOS (metal/oxide film/semiconductor).

As is seen from FIG. 5, the leak current density is greatly different with samples, which were obtained by setting the distance D between the plasma confining electrode 20 and the substrate 3 to 300 and 60 mm, respectively.

The film sample obtained by setting the distance D between the plasma confining electrode 20 and the base 3 to 60 mm, has a leak current characteristic close to that of thermal silicon oxide film and satisfactory, and it also has such electric insulating characteristic and breakdown voltage that it can be used as gate insulating film or inter-layer insulating film of thin film transistor.

On the other hand, the film sample obtained by setting the distance D between the plasma confining electrode 20 and the base 3 to 300 mm, has such a leak current characteristic that leak current flows highly from low electric field range, and its dielectric insulating characteristic and breakdown voltage are such low that it can not be used as gate insulating film and inter-layer insulating film of thin film transistor.

As a further experimental condition in this example, the mean free path λ_{g} of the oxygen/monosilane blend gas in the substrate processing zone R was set to about 60 μm.

This means that the distance D of 300 mm between the plasma confining electrode 20, in which the electric insulating characteristic and breakdown voltage are inadequate, and the substrate 3 corresponds to about 5,000 times the mean free path λ_{g}.

On the other hand, the distance D of 60 mm between the other plasma confining electrode 20, in which the electric insulating characteristic and breakdown voltage are adequate, corresponds to about 1,000 times the mean free path λ_{g}.

In the case of the long distance D between the plasma confining electrode 20 and the substrate 3 corresponding to about 5,000 times the mean free path λ_{g}, it is estimated that the gas phase chemical reaction of oxygen radicals and oxygen molecules 21 with monosilane gas 19 takes place excessively, thus resulting in deposition of particles, which are grown as particle growth in the gas phase in the substrate processing zone R, and consequent coarse film formed on the surface of the substrate 3.

In contrast, in the case of the distance D between the plasma confining electrode 20 and the substrate 3 corresponding to about 1,000 times the mean free path g, it is estimated that the gas phase chemical reaction of oxygen radicals and oxygen molecules 21 with monosilane gas 21 takes place not excessively, thus restricting the particle growth in the gas phase and eliminating deposition of silicon oxide film formation precursor in particle form as film on the surface of the substrate 3.

As described above, in the parallel plate remote plasma CVD the plasma density in the space between the plasma confining electrode 20 and the back electrode 2 is very low, and it is thus possible to suppress the plasma damage to the substrate 3 to be very little compared to the case of the usual parallel plate plasma CVD.

This effect is pronounced in the case when the surface of the substrate 3 is a silicon surface forming a MOS interface. Specifically, in the case of formation of SiO₂ film on single crystal silicon substrate by the usual parallel plate plasma CVD the MOS surface state density is 10¹¹ to 10¹²cm⁻²eV⁻¹ in the neighborhood of the mid gap, whereas in the case of silicon oxide film formation by the parallel plate remote plasma CVD the surface density is as low as at most 10¹⁰ cm⁻²eV⁻¹.

While one embodiment of the present invention has been described in detail with reference to drawings, its specific construction is by no means limitative, design changes and modifications may be made without departing from the scope of the present invention.

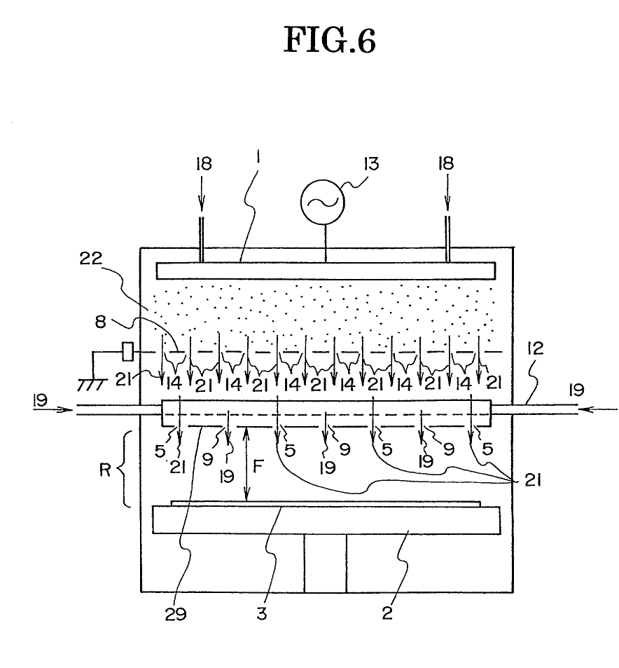

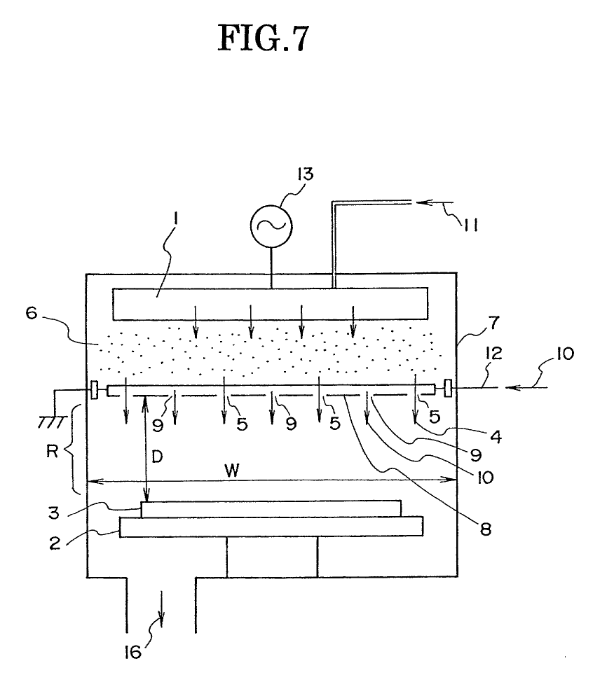

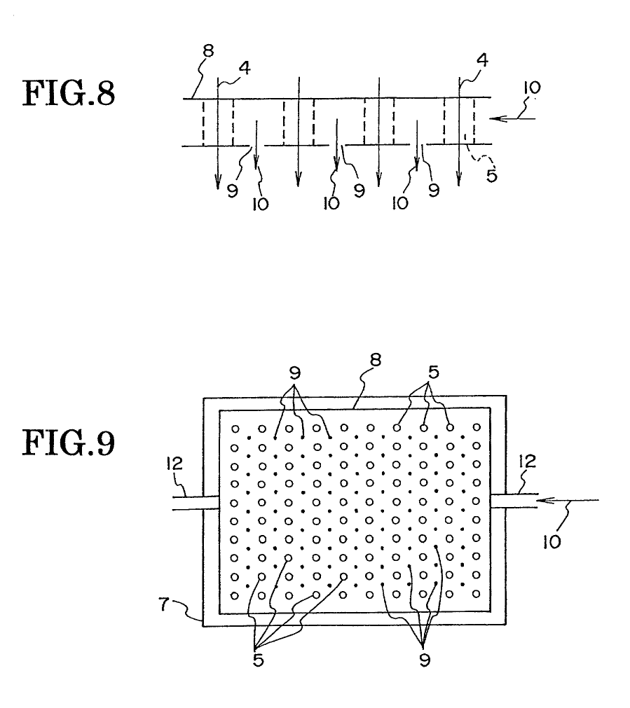

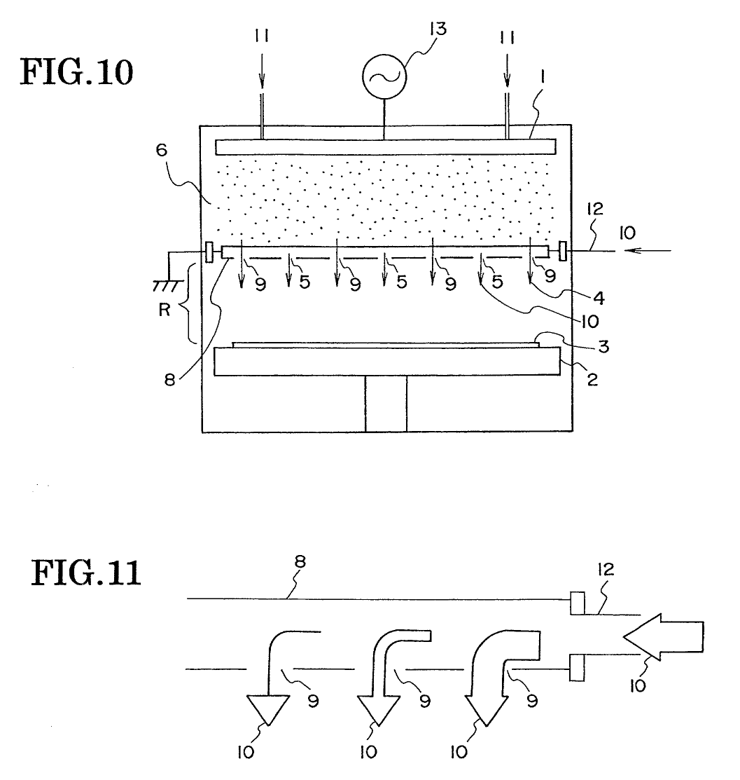

Parallel plate remote plasma CVD in a second embodiment of the present invention will now be described with reference to FIG. 6. FIG. 6 is a schematic sectional view showing a parallel plate remote plasma CVD apparatus embodying the present invention. In the Figure, elements like those in the prior art example and the preceding embodiment are designated by like reference numerals, and are not described.

Referring to FIG. 6, the illustrated parallel plate remote plasma CVD is different from the parallel plate remote plasma CVD apparatus shown in FIG. 1 in that it comprises a gas introducing member 29, which neutral gas (i.e., monosilane gas 19) is supplied into from a neutral gas supply duct line 12 connected to it, and accommodates dispersing plates for uniformalizing the gas density before jetting-out of gas toward substrate, does not have any plasma confining function.

Thus, the gas introducing member 29 accommodating the dispersing plates may have radical passing holes 5 having any diameter so long as radicals 4 can be jetted out uniformly. It is also possible to use the member 29 without being grounded, i.e., in an electrically floated state. It will be seen that the gas introducing member 29 is different from the plasma confining electrode 20 in the previous embodiment in the freedom from being grounded and also in the diameter of the radical passing holes, although it has the same construction.

The gas introducing member 29 is disposed between plasma confining electrode 8 and back electrode 2, and its distance F from substrate 3 is set to be no longer than 1,500 (excluding 0) times the mean free path λ_{g} of blend gas of oxygen (i.e., oxygen radicals and oxygen molecules 21) and monosilane in the substrate processing zone R.

For the remainder, the gas introducing member 29 accommodating the dispersing plates, in the second embodiment, is the same in construction as the plasma confining electrode 20 which also accommodates dispersing plates.

The concept of the structure of the dispersing plates in the gas introducing member 29 and the relationship among the number of dispersing plates, and the distribution of the radical passing holes in the dispersing plates and the neutral gas passing holes therein, is the same as the concept of the dispersing plates (i.e., first and second dispersing plates) in the plasma confining electrode 20 in the first embodiment.

Also, the concept of the distance F between the gas introducing member 29 and the substrate 3 is the same as the concept of the distance D in the plasma confining electrode 29 and the substrate 3 in the plasma confining electrode 20 in the first embodiment. Thus, the gas phase chemical reaction of oxygen radicals and oxygen molecules 21 with monosilane gas 19 does not take place excessively, thus restricting the particle growth in the gas phase and eliminating deposition of particles as film on the surface of the substrate 3.

In the above first and second embodiments, the present invention was described in connection with silicon oxide film formation using monosilane and oxygen. However, it is possible to replace monosilane with higher degree silane such as disilane or such liquid Si material as TEOS (tetra ethoxysilane, and it is also possible to replace oxygen with nitrous oxide, nitrogen oxide, etc.

Also, while the above embodiments were described in connection with the silicon oxide film formation with the remote plasma CVD apparatus, it is possible to obtain the same effects as the films formed in the embodiments with films, which are formed with plasma CVD apparatuses involving gas phase chemical reaction with other materials such as silicon nitride film formation by reaction of monosilane and ammonia with each other.

Furthermore, while the above embodiments were described in connection with the parallel plate remote plasma CVD apparatus, the present invention is applicable as well to any other type of apparatus such as those utilizing microwave plasma, electronic cyclotron resonant plasma, inductively coupled plasma, helicon wave plasma, etc. insofar as the plasma CVC apparatus includes a plurality of holes between the plasma generating region and the substrate processing region R, and employs a plasma confining electrode for plasma separation.

As has been described in the foregoing, with the remote plasma CVD apparatus for forming film by gas phase chemical reaction according to the present invention, it is possible to suppress excessive progress of the gas phase chemical reaction and obtain uniform concentration of neutral gas jetted out in the outside-plasma zone over the deposition substrate.

It is thus possible, with the remote plasma CVD apparatus according to the present invention to form a dense film free from any particle on a large area substrate in the manufacture of gate insulating film or inter-layer insulating film of MOS element.

Changes in construction will occur to those skilled in the art and various apparently different modifications and embodiments may be made without departing from the scope of the present invention. The matter set forth in the foregoing description and accompanying drawings is offered by way of illustration only. It is therefore intended that the foregoing description be regarded as illustrative rather than limiting.

What is claimed is:

1. A plasma CVD apparatus comprising a substrate processing zone with a deposition substrate disposed therein, a plasma generating zone for generating plasma of first gas, and a plasma confining electrode for separating the substrate processing zone and the plasma generating zone and confining the first gas and having holes for passing first gas containing neutral radicals from the first gas plasma, wherein:
the plasma confining electrode has a hollow structure, accommodates gas dispersing plates for uniformalizing second gas in the plasma confining electrode, and has holes for introducing the second gas into the substrate processing zone to form a desired film on the deposition substrate by gas phase chemical reaction of the first gas containing neutral radicals and the second gas with each other; and
the vertical distance between the plasma confining electrode and the deposition substrate is no longer than 1,500 times the mean free path λ_{g} of blend gas of neutral radicals and the second gas in the substrate processing zone at the time of film formation.

2. The plasma CVD apparatus according to claim 1, wherein a plurality of parallel dispersing panels are disposed as the afore-said dispersing plates in the plasma confining electrode.

3. A plasma CVD film forming method comprising:
a first step of forming plasma of first gas in a plasma generating zone;
a second step of confining the plasma in the plasma generating zone with a plasma confining electrode member;
a third step, in which the plasma confining electrode member passes through holes formed therein neutral radicals from the plasma to a substrate processing zone;
a fourth step, in which the plasma confining electrode member supplies uniformalized second gas, with dispersing plates disposed in the member for uniformalizing the second gas, to the substrate processing zone with a deposition substrate disposed therein; and
a fifth step of forming a desired film on the deposition substrate by gas phase chemical reaction of the first gas containing neutral radicals and the second gas;
wherein:
the vertical distance between the plasma confining electrode member and the deposition substrate is no longer than about 1,500 times the mean free path λ_{g} in the substrate processing zone at the time of film generation.

4. A plasma CVD apparatus comprising a substrate processing zone with a deposition substrate disposed therein, a plasma generating zone for generating plasma of first gas, and a plasma confining electrode for separating the substrate processing zone and the plasma generating zone and confining the first gas and having holes for passing first gas containing neutral radicals from the first gas plasma, wherein:
the plasma CVD apparatus further comprises a gas introducing member disposed between the plasma confining electrode member and the deposition substrate and having a plurality of holes, through which second gas is introduced into the substrate processing zone to form a desired film on the deposition substrate by gas phase chemical reaction between the first gas containing neutral radicals and the second gas; and
the gas introducing member has a hollow structure, accommodates dispersing plates for uniformalizing the second gas in it and is vertically spaced apart by a distance no longer than about 1,500 times the mean free path λ_{g} in the substrate processing zone.

5. The plasma CVD according to claim 4, wherein a plurality of parallel dispersing plates are disposed as the afore-said dispersing planes in the gas introducing member.

6. A plasma CVD film forming method comprising:
a first step of forming plasma of first gas in a plasma generating zone;
a second step of confining the plasma in the plasma generating zone with a plasma confining electrode member;
a third step, in which the plasma confining electrode member supplies first gas containing neutral radicals through its holes from the plasma to a space between the plasma confining electrode member and a gas introducing member;
a fourth step, in which the gas introducing member passes first gas containing neutral radicals through its holes to the substrate processing zone with a deposition substrate disposed therein;
a fifth step, in which the gas introducing member supplies uniformalized second gas to the substrate processing zone with dispersing plates disposed in it for uniformalizing the second gas; and
a sixth step of forming a desired film on the deposition substrate by gas phase chemical reaction between the first gas containing neutral radicals and the second gas;
wherein:
the gas introducing member is spaced apart from the deposition substrate by a vertical distance no longer than about 1,500 times the mean free path λ_{g} in the substrate processing zone.
